(19) United States
(12) Patent Application Publication
(10) Pub. No.: US 2012/0326727 A1
(43) Pub. Date: Dec. 27, 2012

(54) COMPOUND TEST METHOD OF HIGH VOLTAGE DIRECT CURRENT TRANSMISSION CONVERTER VALVE

(76) Inventors: Zunpeng Zha, Beijing (CN); Jun Yang, Beijing (CN); Chong Gao, Beijing (CN)

(21) Appl. No.: 13/255,507

(22) PCT Filed: Jun. 16, 2011
(86) PCT No.: PCT/CN11/01002

§ 371 Date: Sep. 9, 2011

(30) Foreign Application Priority Data
Dec. 1, 2010 (CN) 201010576661.0

(51) Int. Cl. G01R 1/00

(52) U.S. Cl. 324/555

(57) ABSTRACT

The present provided a compound test method of high voltage direct current transmission converter valve. The invention method adopted two independent high voltage sources to supply forward and reverse high voltage in blocking interval. It causes that the test voltage of the test valve is more close to that of the real operation. The experiment equivalence is better. Moreover, by controlling the scheduling of two high voltage sources, it can produce more waveforms, can choose different combination according to program requirements and design character; this method has large choice room and flexibility.

### FIELD OF THE INVENTION

The present invention relates to electric power and power simulation test field, relates specially to a test method of direct current transmission converter valve, and relates particularly to a compound test method of high voltage direct current transmission converter valve.

### BACKGROUND OF THE INVENTION

With the improvement of direct current transmission voltage and capacity, direct current converter valve which is the key device of the direct current transmission system is very important for system operation safely. The direct current transmission converter valve has some features like high working voltage, high current, high capacity; it is very difficult to make up a same full-laden test circuit to real operation condition. So it become a key how to make up a equivalent test circuit same to real condition.

Due to the test capacity limit, now compound test method is adopted generally to carry on the direct current converter working test. The basic idea is that two power sources provide long time working current and high voltage for the direct current converter valve respectively. The source which provides working current for the test valve is a high current source, and the source which provides working high voltage is high voltage source. But exiting compound test circuit whose high voltage source consists of clap circuits has a notable feature--symmetrical the forward and reverse high voltage. In practice operation, the converter valve reverse and forward voltage is not symmetrical. Although the test fulfills common engineering requirements, its equivalence is not satisfactory enough.

### SUMMARY OF THE INVENTION

This aim of this invention is to provide a compound test method of high voltage direct current transmission converter valve. It adopted two high voltage sources to provide blocking interval forward and reverse high voltage for test valve, high direct current sources provide conducting interval high direct current for test valve, put the high voltage and direct current on the test valve with working frequency

To achieve above aims, this invention adopts following technology:

A compound test method of high voltage direct current transmission converter valve is characterized that is characterized that the equipment used for this test method is direct current converter valve compound test equipment, said equipment includes test valve Vt, low voltage large current source 1 and two high voltage sources, said two high voltage sources is the high voltage source 2 and the source 3, said the high voltage source 2 is parallel connected with source 3.

In the first optimization of this invention, wherein said low voltage large current source 1 is parallel connected with test valve Vt, said high voltage source 2 includes auxiliary valve V1, charge device S1, resonant inductor L1 and resonant capacitor C2, said charge device S1 is parallel connected with resonant capacitor C1, then connected with resonant inductor L1 and auxiliary valve V1 in series, said high voltage source 3 includes auxiliary valve V2, charge device S2, resonant inductor L2 and resonant capacitor C2; said charge device S2 is connected with resonant capacitor C2 in parallel, and then connected with resonant inductor L2 and auxiliary valve V2 in series, said high voltage source 2 and 3 is connected with test valve Vt in parallel.

In the second optimization of this invention, said method includes following steps:

A, high voltage source charge for resonant capacitor, and turn on low voltage large direct current source at the same time;

B, turn on the test valve and auxiliary valve according to control system command;

C, test valve affords conducting interval large current and blocking interval high voltage.

In the third optimization of this invention,

Wherein said step A, high voltage source 2 and 3 are forward and reverse voltage brought by resonant capacitor C1 and C2 charge respectively, at the same time turn on low voltage large direct current source 1 produces large direct current;

Wherein said step B, during the compound test period, turn on test valve Vt, auxiliary valve V1 and V2 according to control system command;

Wherein said step C, the resonant current of high voltage source 2 and 3 passes through test Vt, direct current of the low voltage large direct current source 1 passes through test valve Vt, the valve Vt affords conducting interval large current and blocking interval high voltage.

In the third optimization of this invention, wherein said forward and reverse high for test valve Vt are not symmetrical which is supplied independently by two high voltage source 2 and 3 in blocking interval.

Compared with present technology, the beneficial effects of this invention are described as below:

1, In the compound test method, the forward and reverse voltage of the test valve are supplied by two independent high voltage source in blocking interval, and test valve can acquire symmetrical blocking voltage, and make the voltage is more close to real operation voltage waveform, the test effect is better.

2, By change the control scheduling, this method can realize a variety of voltage combination, can choose different combination according to different test program and design character, this method has large choice room, flexible way and wide application.

### BRIEF DESCRIPTION OF THE DRAWINGS

Currently preferred embodiments of the invention will now be described with reference to the following attached drawings in which:

FIG. 1 is schematic diagram of compound test equipment of the high voltage direct current converter valve;

FIG. 2 is voltage and current waveform graph of the compound test method under double injection mode;

FIG. 3 is voltage and current waveform graph of the compound test method under triplicate injection mode;

### DETAILED DESCRIPTION OF EMBODIMENTS

The detail of the embodiments is described as below incorporated with the figures by way of cross-reference.

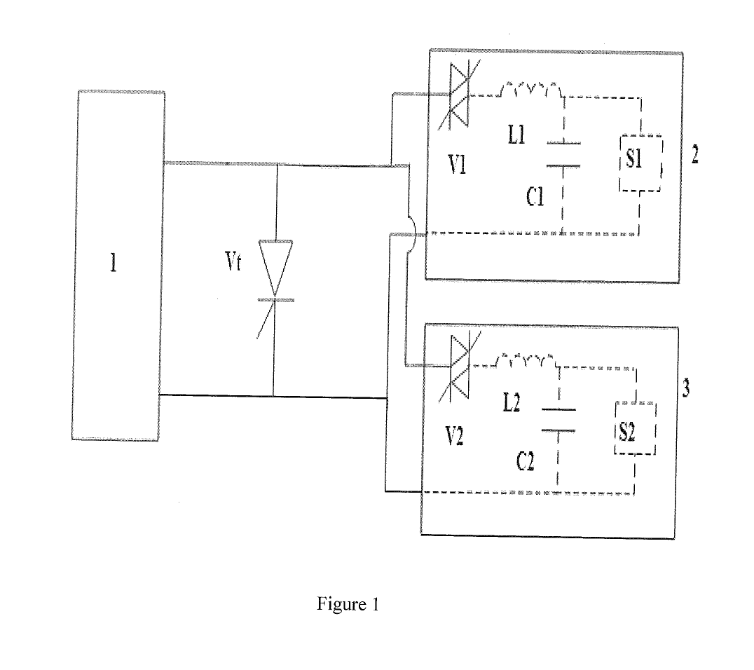

FIG. 1 is schematic diagram of compound test equipment of the high voltage direct current converter valve. This equipment includes test valve Vt, low voltage large direct current source 1, high voltage source 2 and high voltage source 3; the low voltage large direct current source 1 is connected with test valve Vt in parallel; high voltage 2 includes auxiliary valve V1, charge device S1, resonant capacitor L1 and resonant capacitor C1; charge device S1 is connected with resonant capacitor C1 in parallel and then connected with resonant inductor L1 and auxiliary valve V1 in series; high voltage source 3 includes auxiliary valve V2, charge device S2, resonant inductor L2 and resonant capacitor C2, the charge device S2 is connected with resonant capacitor C2 in parallel, and then connected with resonant inductor L2 and auxiliary valve V2 in series; high voltage source 2 and 3 are parallel connected with test valve Vt.

The independent high voltage source 2 and 3 supply the forward and reverse high voltage which are produced by resonant capacitor C1 and C1 respectively to provide the forward triggering voltage and the reverse recovery voltage after test valve hold off, and test valve voltage jump and forward voltage rise rate in blocking interval. This can access the fetch unit design of the test valve Vt. At the same time, bring the resonant current of high voltage source 2 and 3 through low voltage large direct current source 1 turning off to equal the current change rate before test valve Vt turning off; low voltage large direct current source 1 supplies direct current for test valve Vt during conducting interval to equal the peak current of the test valve Vt, and reappear test valve Vt loss during conducting interval; before the hundreds of seconds of high voltage source current blocking, the current of low voltage large direct current source 1 is over zero and blocked, at the same time, the auxiliary valve V1 and V2 is turned off to ensure their safety; the auxiliary valve V1, V2 and test valve Vt is turned on according to the certain periodical trigging scheduling by the control system command, which make them to afford large current of conducting interval and high voltage in blocking interval; independent high voltage source 2 and 3 supply forward and reverse dissymmetrical high voltage for test valve Vt, the high voltage source 2 and 3 can produce kinds of voltage waveforms according to arranging the scheduling.

The detail of the voltage and current periodical waveforms of this invention circuit under two working modes are described as below incorporated with embodiments.

### EXAMPLE 1

In the high voltage direct current converter compound test, this invention method working principle is described as below under the double injection mode:

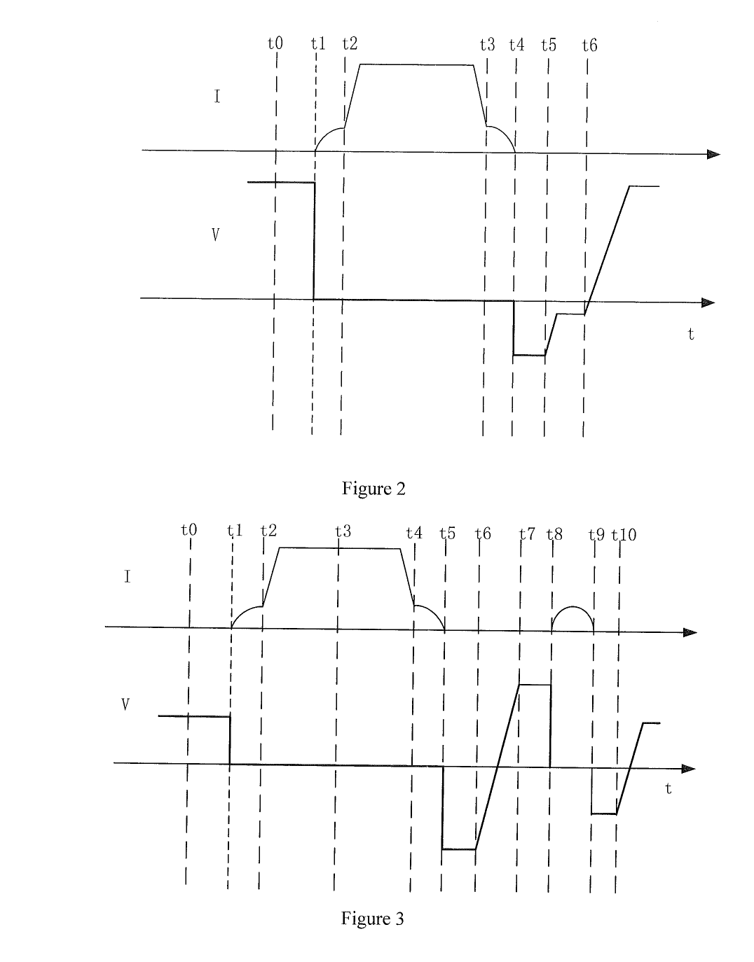

FIG. 2 is the voltage and current periodical waveform graph (20 ms) of the test valve under double injection mode in the compound test.

At t0, the test valve affords forward high voltage from high voltage source 2;

At t1, turn on the test valve Vt and auxiliary valve V1, and the resonant current from the high voltage source 2 passes through the test valve Vt;

At t2, bring the current from the large direct current source 1 into test vavle Vt, and it affords the direct current in conducting interval;

At t3, turn on the auxiliary V2 before direct current off, and the resonant current from the high voltage source 3 passes through test valve Vt;

At t4, the resonant current from the high voltage source 3 is off, trigger auxiliary valve V2, and the test valve Vt afford reserve high voltage from the high voltage 3 after the test valve Vt off;

At t5, charge for high voltage source 3 by controlling charge device S2;

At t6, charge for high voltage source 2 by controlling charge device S1, trigger auxiliary valve V1 with wide pulse to supply forward high voltage for the test valve Vt which is from high voltage source 2, and the test circuit is ready for next test cycle.

### EXAMPLE 2

In the high voltage direct current converter compound test, this invention method working principle is described as below under the triplicate injection mode:

FIG. 3 is the voltage and current periodical waveform graph (20 ms) of the test valve under triplicate injection mode in the compound test.

At t0, the test valve affords forward high voltage from high voltage source 2;

At t1, turn on the test valve Vt and auxiliary valve V1, and the resonant current from the high voltage source 2 passes through the test valve Vt;

At t2, bring the current from the large direct current source 1 into test vavle Vt, and it affords the direct current in conducting interval;

At t3, charge device S1 charges resonant capacitor C1 of the high voltage source 2, to recovery its voltage to t0 level;

At t4, turn on the auxiliary V2 before the direct current off, the resonant current from high voltage source 3 passes through the test valve;

At t5, the resonant current from the high voltage source 3 is off, trigger auxiliary valve V2, and the test valve Vt afford reserve high voltage from the high voltage 3 after the test valve Vt off;

At t6, charge for high voltage source 3 by controlling charge device S2, at the same time auxiliary valve V2 is supplied wide triggering pulse;

At t7, complete charging the resonant capacitor C2 of the high voltage source 3, the test valve Vt affords forward high voltage;

At t8, turn on test valve Vt and auxiliary valve V1, resonant current from high voltage source 2 passes through test valve again;

At t9, resonant current is over zero, turn on auxiliary valve V1, test will afford reverse high voltage;

At t10, charge device S1 charges for resonant capacitor C1 of high voltage source 2, after charge the test circuit is ready for next test cycle.

The invention method adopted two independent high voltage sources to supply forward and reverse high voltage in blocking interval. It causes that the test voltage of the test valve is more close to that of the real operation. The experiment equivalence is better. Moreover, by controlling the scheduling of two high voltage sources, it can produce more waveforms, can choose different combination according to program requirements and design character; this method has large choice room and flexibility.

At last, the detail embodiment is one example of the invention but not the only one, so the person in this field must be understand that all the alternatives and other equal and/or similar examples are all within the range of the invention and they are all consistent with the spirits of this invention, are all protected by our claims.

1. A compound test method of high voltage direct current transmission converter valve is characterized that the equipment used for this test method is direct current converter valve compound test equipment, said equipment includes test valve Vt, low voltage large current source (1) and two high voltage sources, said two high voltage sources is the high voltage source (2) and the source (3), said the high voltage source (2) is parallel connected with source (3).

2. A compound test method of high voltage direct current transmission converter valve according to claim 1, wherein said low voltage large current source (1) is parallel connected with test valve Vt, said high voltage source (2) includes auxiliary valve V1, charge device S1, resonant inductor L1 and resonant capacitor C2, said charge device S1 is parallel connected with resonant capacitor C1, then connected with resonant inductor L1 and auxiliary valve V1 in series, said high voltage source (3) includes auxiliary valve V2, charge device S2, resonant inductor L2 and resonant capacitor C2; said charge device S2 is connected with resonant capacitor C2 in parallel, and then connected with resonant inductor L2 and auxiliary valve V2 in series, said high voltage source (2) and (3) is connected with test valve Vt in parallel.

3. A compound test method of high voltage direct current transmission converter valve according to claim 1, wherein said method includes following steps:
A, high voltage source charge for resonant capacitor, and turn on low voltage large direct current source at the same time;
B, turn on the test valve and auxiliary valve according to control system command;
C, test valve affords conducting interval large current and blocking interval high voltage.

4. A compound test method of high voltage direct current transmission converter valve according to claim 1,
Wherein said step A, high voltage source (2) and (3) are forward and reverse voltage brought by resonant capacitor C1 and C2 charge respectively, at the same time turn on low voltage large direct current source (1) produces large direct current;
Wherein said step B, during the compound test period, turn on test valve Vt, auxiliary valve V1 and V2 according to control system command;
Wherein said step C, the resonant current of high voltage source (2) and (3) passes through test Vt, direct current of the low voltage large direct current source (1) passes through test valve Vt, the valve Vt affords conducting interval large current and blocking interval high voltage.

5. A compound test method of high voltage direct current transmission converter valve according to claim 1, wherein said the forward and reverse high for test valve Vt are not symmetrical which is supplied independently by two high voltage source (2) and (3) in blocking interval.
